(19) United States
(12) Patent Application Publication
(10) Pub. No.: US 2026/0144008 A1
(43) Pub. Date: May 21, 2026

(54) SEMICONDUCTOR MANUFACTURING DEVICE AND TEACHING APPARATUS INCLUDING THE SAME

(71) Applicant: Samsung Electronics Co., Ltd., Suwon-si (KR)

(72) Inventors: JONGWHA LEE, Suwon-si (KR); DONG-JIN LIM, Suwon-si (KR); HYOIL CHIO, Suwon-si (KR); DEA WOONG HAN, Suwon-si (KR)

(21) Appl. No.: 19/394,356

(22) Filed: Nov. 19, 2025

(30) Foreign Application Priority Data
Nov. 20, 2024 (KR) 10-2024-0166729

(51) Int. Cl. H01L 21/687; B08B 3/04; H01J 37/32; H01L 21/677; H01L 21/68

(52) U.S. Cl. CPC H10P 72/7602; B08B 3/04; H01J 37/32642; H01J 37/32743; H10P 72/33; H10P 72/50; H10P 72/7611; H01J 2237/204; H01J 2237/335; H10P 72/3218

(57) ABSTRACT

A semiconductor manufacturing apparatus includes a process chamber, a wafer support plate disposed inside the process chamber, an edge ring disposed inside the process chamber and surrounding the wafer support plate, and a robot including a control circuit and a gripper. The control circuit controls the gripper to load a dummy wafer having a first diameter on the wafer support plate during a cleaning process and load a wafer having a second diameter, greater than the first diameter, on the wafer support plate during a mass production process, the gripper being adjustable to accommodate the dummy wafer having the first diameter and the wafer having the second diameter, and controls the robot to place a center of the dummy wafer at a center of the wafer support plate during the cleaning process.

### CROSS-REFERENCE TO RELATED APPLICATION(S)

This U.S. non-provisional application claims priority under 35 USC § 119 to Korean Patent Application No. 10-2024-0166729, filed on Nov. 20, 2024, in the Korean Intellectual Property Office, the disclosure of which is herein incorporated by reference in its entirety.

### BACKGROUND

Example embodiments relate to a semiconductor manufacturing device and a teaching apparatus including the same.

A desired pattern may be formed on a wafer through various mass production processes, such as lithography, etching, ion implantation, or thin film deposition, to manufacture a semiconductor device. Various chemicals are used in each process, and contaminants such as particles and polymers are generated as a result of the process. Before and after each mass production process, a process of cleaning the wafer is performed remove these contaminants.

As semiconductor mass production processes become more complex and precise, it is becoming increasingly difficult to remove these contaminants, and a cleaning process is taking more times. Accordingly, the need for technology to efficiently perform the cleaning process is increasing.

### SUMMARY

Example embodiments provide a semiconductor manufacturing device capable of efficiently performing a cleaning process.

According to an aspect of the present disclosure, a semiconductor manufacturing apparatus includes a process chamber, a wafer support plate disposed inside the process chamber, an edge ring disposed inside the process chamber and surrounding the wafer support plate, and a robot including a control circuit and a gripper. The control circuit controls the gripper to load a dummy wafer having a first diameter on the wafer support plate during a cleaning process and load a wafer having a second diameter, greater than the first diameter, on the wafer support plate during a mass production process, the gripper being adjustable to accommodate the dummy wafer having the first diameter and the wafer having the second diameter, and controls the robot to place a center of the dummy wafer at a center of the wafer support plate during the cleaning process.

According to an aspect of the present disclosure, a method of operating a semiconductor processing apparatus includes performing a first mass production process on a first wafer placed on a wafer support plate which is surround by an edge ring with an upper surface including a first upper surface higher than an upper surface of the wafer support plate, a second upper surface lower than the first upper surface, and a side surface connecting the first upper surface to the second upper surface, wherein the first wafer covers the second upper surface and exposes the first upper surface and the side surface, receiving a first robot moving value for a first cleaning process from a memory after the performing of the first mass production process, performing a first alignment operation based on the first robot moving value to align a center of a dummy wafer with a center of the wafer support plate, wherein the dummy wafer exposes the first upper surface, the second upper surface, and the side surface, and performing the first cleaning process on the upper surface of the edge ring after the performing of the first alignment operation.

According to an aspect of the present disclosure, a plasma processing apparatus includes a plasma process chamber, a wafer support plate disposed inside the plasma process chamber and configured to support one of a dummy wafer and a wafer, an edge ring disposed inside the plasma process chamber and surrounding the wafer support plate, and a robot including a control circuit and a gripper. The control circuit controls the gripper to load the dummy wafer having a first diameter on the wafer support plate during a cleaning process and load the wafer having a second diameter, greater than the first diameter, on the wafer support plate during a mass production process, the gripper being adjustable to accommodate the dummy wafer having the first diameter and the wafer having the second diameter, and controls the robot to place a center of the dummy wafer at a center of the wafer support plate during the cleaning process.

### BRIEF DESCRIPTION OF DRAWINGS

FIG. 1 is a diagram illustrating a semiconductor manufacturing system according to an example embodiment.

FIG. 2A is a diagram illustrating a semiconductor manufacturing device with a seated cover wafer according to an example embodiment.

FIG. 2B is a more detailed diagram of first region R1 of FIG. 2A.

FIG. 3A is a diagram illustrating a semiconductor manufacturing device with a seated production wafer according to an example embodiment.

FIG. 3B is a more detailed diagram of a second region R2 of FIG. 3A.

FIGS. 4A and 4B are diagrams illustrating an example in which a diameter of the cover wafer and a diameter of the mass production wafer are the same.

FIG. 5 is a diagram illustrating an example of a teaching apparatus according to an example embodiment.

FIG. 6 is a timing diagram illustrating an example of a semiconductor manufacturing process in which a mass production process and a cleaning process are repeatedly performed.

FIGS. 7A to 7F are diagrams illustrating an example of an alignment operation in a mass production process and a cleaning process according to an example embodiment.

FIG. 8 is a flowchart illustrating a cover wafer-ESC alignment operation according to an example embodiment.

FIG. 9 is a flowchart illustrating a mass production wafer-ESC alignment operation according to an example embodiment.

### DETAILED DESCRIPTION

Hereinafter, example embodiments will be described in detail and clearly to such an extent that those skilled in the art may easily implement the example embodiments. Hereinafter, D1 may be referred to as a first direction, D2 may be referred to as a second direction intersecting the first direction D1, and D3 may be referred to as a third direction intersecting both the first direction D1 and the second direction D2. The first direction D1 may also be referred to as a vertical direction. Each of the second direction D2 and the third direction D3 may be referred to as a horizontal direction.

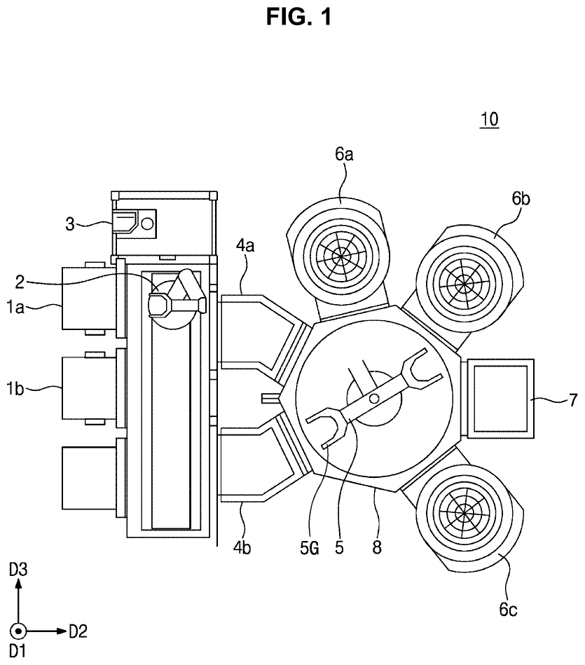

FIG. 1 is a diagram illustrating a semiconductor manufacturing system 10 according to an example embodiment.

Referring to FIG. 1, the semiconductor manufacturing system 10 may include first and second loading pods 1a and 1b, a first robot 2, an aligner 3, first and second loadlock chambers 4a and 4b, a second robot 5, first to third process chambers 6a, 6b, and 6c, a cooling station 7, and a transfer chamber 8.

The first and second loading pods 1a and 1b may accommodate wafers. For example, wafers may be placed in containers within the first and second loading pods 1a and 1b.

In an example embodiment, a front opening unified pod (FOUP) may be used as the container. The container may be brought into the first and second loading pods 1a and 1b from the outside via overhead transfer (OHT). The container may be taken out from the first and second loading pods 1a and 1b to the outside via OHT.

The first robot 2 may transfer wafers, loaded in the first and second loading pods 1a and 1b, to the aligner 3.

The aligner 3 may receive the wafers, loaded in the first and second loading pods 1a and 1b, through the first robot 2 and align the received wafers.

The first and second loadlock chambers 4a and 4b may receive wafers from the aligner 3 through the first robot 2. For example, each of the first and second loadlock chambers 4a and 4b may include a cassette. The wafers aligned by the aligner 3 may be transferred by the first robot 2 into the cassettes within the first and second loadlock chambers 4a and 4b.

When all the wafers are transferred to the first and second loadlock chambers 4a and 4b, doors of the first and second loadlock chambers 4a and 4b may be closed. Then, air inside the first and second loadlock chambers 4a and 4b may be removed and the first and second loadlock chambers 4a and 4b may be evacuated to establish a vacuum to prevent impurities from entering the loadlock chambers 4a and 4b.

The second robot 5 may transfer the wafers, loaded in the cassettes of the first and second loadlock chambers 4a and 4b, to the first to third process chambers 6a, 6b, and 6c.

Each of the first to third process chambers 6a, 6b, and 6c may perform a predetermined process. For example, the predetermined process performed by each of the first to third process chambers 6a, 6b, and 6c may include a mass production process and a cleaning process. The mass production process may refer to processes other than the cleaning process. For example, the mass production process may include etching including plasma etching, photolithography, deposition, or ion implantation processes. The cleaning process may be performed to remove particles or polymers between mass production processes. During the mass production process, particles or polymers may be generated and deposited on the upper surface of the edge ring, and may remain there after the mass production process is completed. In an example embodiment, the cleaning process may be performed using plasma to remove the particles or polymers from the upper surface of the edge ring. For example, ions present in the plasma generated in the cleaning process may be accelerated to have an energy enough to remove the particles or the polymers from the upper surface of the edge ring.

When each process is completed, the cooling station 7 may receive processed wafers through the second robot 5. For example, the wafers may be heated to a predetermined temperature during a process in the first to third process chambers 6a, 6b, and 6c. The cooling station 7 may receive the processed wafers and cool the received wafers to a temperature before the process.

The transfer chamber 8 may be connected to the first and second loadlock chambers 4a and 4b, the first to third process chambers 6a, 6b, and 6c, and the cooling station 7. The second robot 5 may be disposed in the transfer chamber 8.

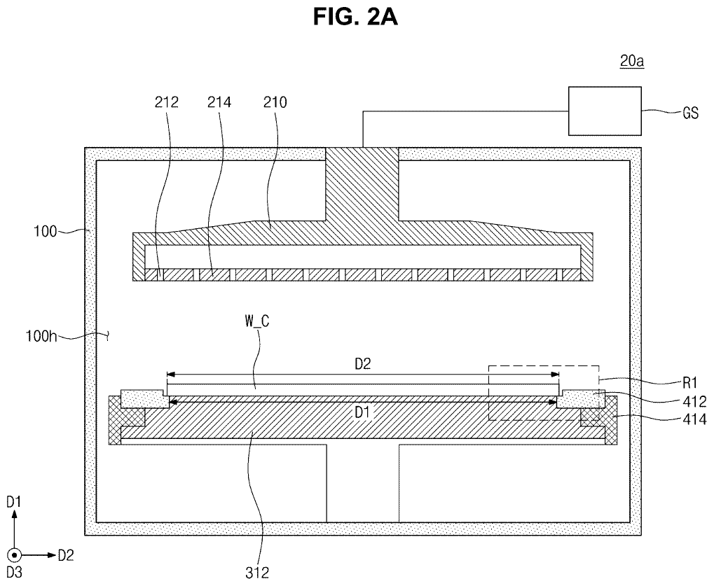

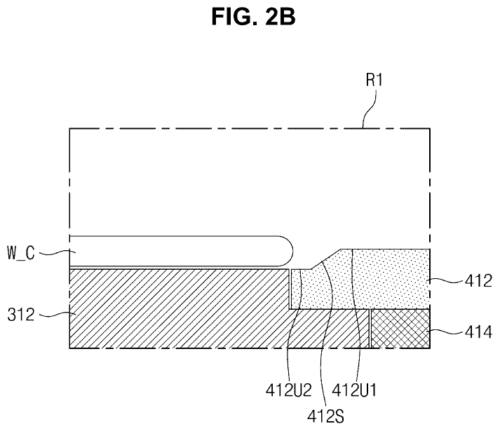

In an example embodiment, a diameter of a cover wafer (i.e., a dummy wafer) used in the cleaning process may be smaller than a diameter of a wafer which is process in the mass production process. Accordingly, contaminants such as polymers accumulated in a pocket portion of the edge ring may be effectively removed in the cleaning process. For example, during a plasma etching process, a polymer (i.e., a polymer residue) may be deposited on at least a portion of an upper surface of the edge ring. This will be described in more detail with reference to FIG. 2A to 4b below.

In an example embodiment, an alignment operation of the second robot 5 may be performed independently in the cleaning process and the mass production process.

For example, during an operation of aligning the cover wafer and the wafer support plate in the cleaning process (hereinafter, referred to as a “cover wafer-ESC alignment operation”), the second robot 5 may seat the cover wafer on the wafer support plate to align the center of the cover wafer with the center of the wafer support plate. In an embodiment, the second robot 5 may include a gripper 5G which accommodates the wafer for the mass production and the cover wafer, having a diameter smaller than that of the wafer, for the cleaning process. In an embodiment, the gripper 5G may grip the cover wafer or the wafer only at the edge to avoid contaminating or damaging an active surface of the wafer at which transistors may be formed. In an embodiment, the gripper 5G may be formed of a material such as Polyether Ether Ketone (PEEK), which is a high-performance thermoplastic polymer, and stainless steel coated with electrostatic discharge (ESD)-safe and non-contaminating material including Teflon. In an embodiment, the gripper 5G may be equipped with sensors such as optical sensors and force/torque sensors for centering and alignment. The gripper 5G may be adjustable to accommodate both the cover wafer for the cleaning process and the wafer for the mass production, which have different diameters.

During an operation of aligning the mass production wafer and the wafer support plate in the mass production process (hereinafter, referred to as a “mass production wafer-ESC alignment operation”), the second robot 5 may vary a target position on the wafer support plate on which the mass production wafer is to be seated, based on the measured values of the detection sensor. The center of the cover wafer may not be aligned with the center of the wafer support plate.

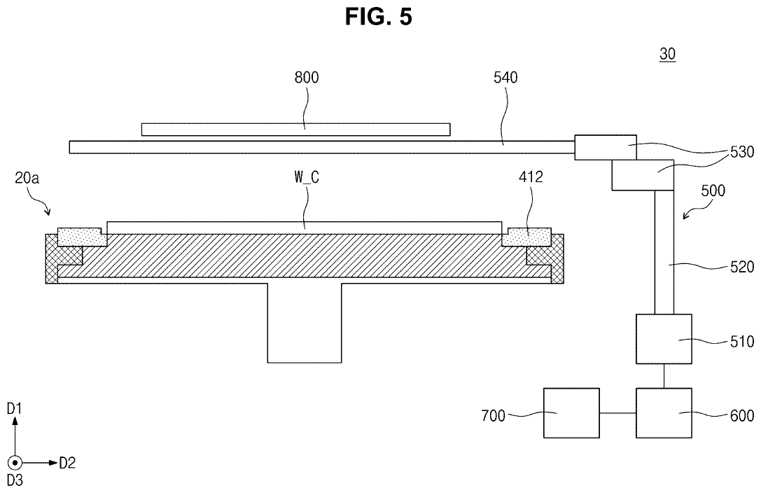

For example, the robot moving value for the second robot 5 may be corrected based on the measured value in the mass production process, but such a correction operation may be skipped in the cleaning process. This will be described in more detail with reference to FIGS. 5 to 9 below.

The number and arrangement of the loading pods, the number and arrangement of the loadlock chambers, and the number and arrangement of the process chambers 6a, 6b, and 6c described in FIG. 1 are merely exemplary, and example embodiments are not limited thereto. According to example embodiments, the number and arrangement of loading pods, loadlock chambers, and process chambers may be changed in various ways.

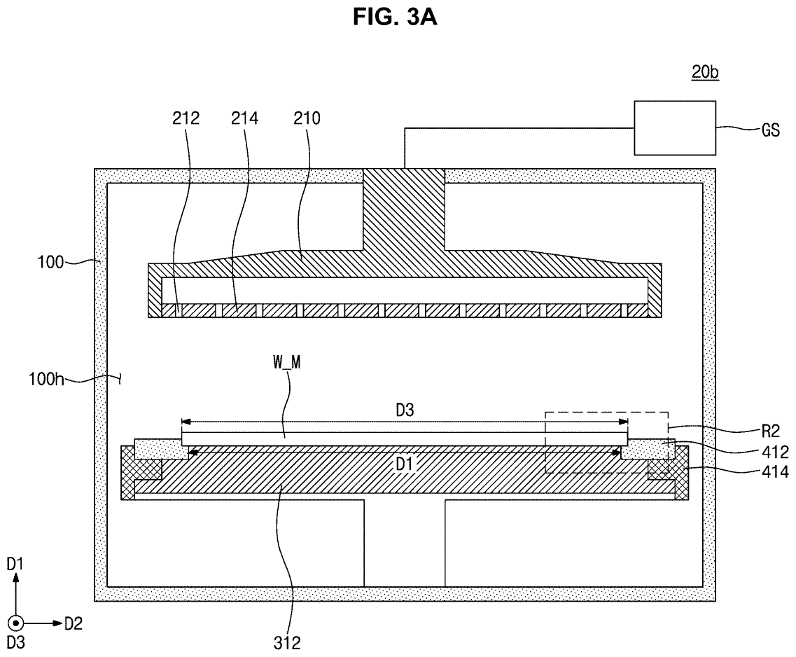

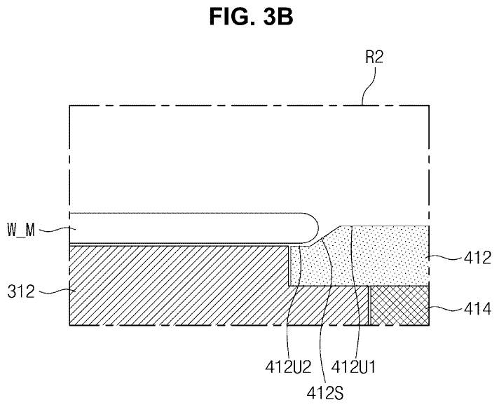

FIG. 2A is a diagram illustrating a semiconductor manufacturing device with a seated cover wafer according to an example embodiment. FIG. 2B is a more detailed diagram of a first region R1 of FIG. 2A. FIG. 3A is a diagram illustrating a semiconductor manufacturing device with a seated production wafer according to an example embodiment. FIG. 3B is a more detailed diagram of a second region R2 of FIG. 3A.

Referring to FIGS. 2A, 2B, 3A and 3B, semiconductor manufacturing devices 20a and 20b may each include a process chamber 100, a shower head 210, a wafer support plate 312, an edge ring 412, and an insulating ring 414.

The process chamber 100 may provide a process space 100h. A process on the wafer may be performed in the process space 100h. The process space 100h may be separated from an external space. The process chamber 100 may be formed of a material having improved wear resistance and corrosion resistance. For example, the process chamber 100 may include an aluminum block, but example embodiments are not limited thereto. The process space 100h may be made into a substantial vacuum state during the process performed on the wafer. To this end, although not illustrated, the process chamber 100 may further include a pump for maintaining the vacuum state.

The process chamber 100 may have, for example, a cylindrical shape. However, this is merely exemplary, and the process chamber 100 may be implemented in various shapes. The process chamber 100 may be one of the process chambers 6a, 6b, and 6c of FIG. 1.

The shower head 210 may be disposed inside the process chamber 100. For example, the shower head 210 may be disposed within the process space 100h. The shower head 210 may be disposed to be spaced apart from the wafer support plate 312 in the first direction D1. Process gas, supplied from a gas supply device GS, may be uniformly injected into the process space 100h through the shower head 210. The first direction D1 may be perpendicular to an upper surface of the wafer support plate 312, and the second and third directions D2 and D3 may be parallel to the upper surface of the wafer support plate 312.

The shower head 210 may include a spray plate 214 having a plurality of injection holes 212 for injecting the process gas. The plurality of injection holes 212 may be radially arranged with respect to a central region of the shower head 210. According to example embodiments, a diffusion plate may be further provided inside the shower head 210 to diffuse the process gas.

The wafer support plate 312 may be disposed inside the process chamber 100. For example, the wafer support plate 312 may be disposed within the process space 100h. The wafer support plate 312 may support and fix a wafer. A wafer may be subjected to a process while seated on the wafer support plate 312.

The wafer support plate 312 may be an electrostatic chuck ESC. The electrostatic chuck may receive power from an electrostatic force supply source. When high-frequency power is applied to the electrostatic chuck, the electrostatic chuck may generate electrostatic force to fix the wafer. For example, when the high-frequency power is applied, the electrostatic chuck may chuck the wafer. When the high-frequency power is not applied to the electrostatic chuck, the electrostatic chuck may separate the wafer. For example, when the high-frequency power is not applied, the electrostatic chuck may dechuck the wafer. In an embodiment, a diameter of the wafer support plate 312 may be smaller than a diameter of the wafer to be processed using the mass production process, and may be equal to or greater than a diameter of the cover wafer. The diameter of the cover wafer may be smaller than the diameter of the wafer to be processed using the mass production process.

The wafer support plate 312 may include a heat conductor, such as a heating wire, and the process temperature may be controlled by the heating conductor. The wafer support plate 312 may include, for example, an aluminum nitride (AlN), but example embodiments are not limited thereto.

The edge ring 412 may have a ring shape surrounding an upper portion of the wafer support plate 312. For example, a portion of the edge ring 412 may surround the upper portion of the wafer support plate 312 on which the wafer is placed. The edge ring 412 may be formed of, for example, silicon (Si), silicon carbide (SiC), or quartz, but example embodiments are not limited thereto.

A step may be formed on an internal side surface of the edge ring 412. For example, the edge ring 412 may include a first upper surface 412U1, a second upper surface 412U2, and a side surface 412S (i.e., an angled side surface) connecting the first upper surface 412U1 and the second upper surface 412U2 with each other, as illustrated in FIGS. 2B and 3B.

The first upper surface 412U1 of the edge ring 412 may be disposed at a higher level than an upper surface of the cover wafer W_C or the mass production wafer W_M, and the second upper surface 412U2 may be disposed at a lower level than the upper surface of the cover wafer W_C or the mass production wafer W_M. According to example embodiments, the second upper surface 412U2 may be referred to as a pocket region of the edge ring 412. The pocket region of the edge ring 412 may be covered by the mass production wafer W_M in the mass production process, and may be exposed by the cover wafer W_C in the cleaning process.

The insulating ring 414 may be disposed under the edge ring 412. The insulating ring 414 may be disposed to surround the side surface of the wafer support plate 312. The insulating ring 414 may protect the wafer support plate 312 from plasma during the mass production process and/or the cleaning process.

In an example embodiment, the cover wafer W_C may be seated on the wafer support plate 312 during the cleaning process. As illustrated in FIG. 2A, a diameter D2 of the cover wafer W_C may be the same as or similar to a diameter D1 of the upper surface of the wafer support plate 312.

As illustrated in FIG. 2B, the side surface 412S of the edge ring 412 may be disposed at a certain distance from the cover wafer W_C. For example, the side surface 412S of the edge ring 412 may be spaced apart from the cover wafer W_C by a certain distance during the cleaning process, and thus the second upper surface 412U2 may be exposed to the outside (e.g., plasma). As a result, contaminants such as polymers accumulated on the second upper surface 412U2 may be removed by plasma during the cleaning process. In an embodiment, the polymers may be further accumulated on the side surface 412S and the first upper surface 412U1, and in the cleaning process, the polymers that are accumulated on the side and first upper surfaces 412S and 412U1 may be removed together with the polymers accumulated on the second upper surface 412U2.

In an example embodiment, the mass production wafer W_M may be seated on the wafer support plate 312 during the mass production process. As illustrated in FIG. 3A, a diameter D3 of the mass production wafer W_M may be larger than the diameter D1 of the upper surface of the wafer support plate 312.

As illustrated in FIG. 3B, the side surface 412S of the edge ring 412 may be in contact with or adjacent to the mass production wafer W_M. For example, the side surface 412S of the edge ring 412 may be in contact with or adjacent to the mass production wafer W_M during the mass production process, and thus the second upper surface 412U2 may be covered by the mass production wafer W_M and may not be exposed to the outside (e.g., the plasma generated during the mass production process).

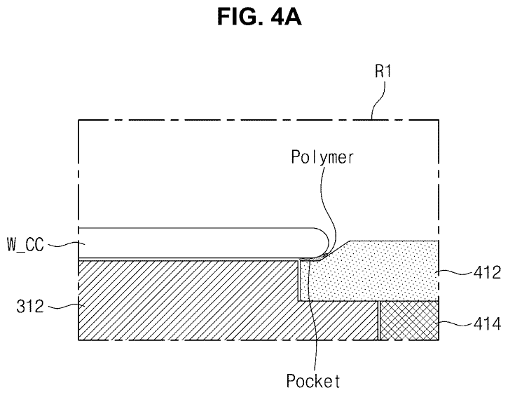

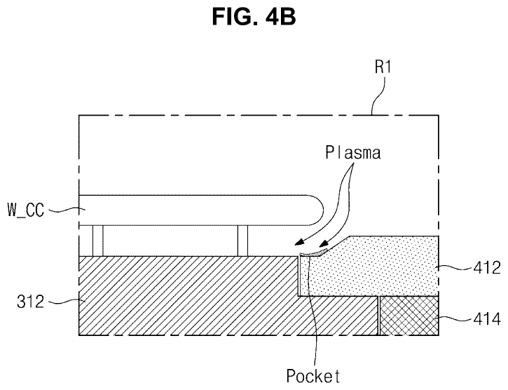

FIGS. 4A and 4B are diagrams illustrating an example in which a diameter of the cover wafer and a diameter of the mass production wafer are the same. For ease of description, an example is provided in which the semiconductor manufacturing device illustrated in FIGS. 4A and 4B has the same structure as the semiconductor manufacturing device illustrated in FIGS. 3A and 3B, except for a cover wafer W_CC for describing a comparative example.

Referring to the comparative example of FIG. 4A, a diameter of a cover wafer W_CC provided in a cleaning process is the same as a diameter of a mass production wafer W_M. Accordingly, polymer accumulated in a pocket portion of an edge ring 412 during the cleaning process may not be exposed to the outside, as illustrated in FIG. 4A. For this reason, the pocket portion may not be exposed to plasma generated in the cleaning process. The polymer residue in the pocket portion of the edge ring may remain after the cleaning process, and may increase a surface temperature of the edge portion of the mass production wafer, resulting in issues such as poor etching or arcing.

Alternatively, referring to the comparative example of FIG. 4B, a cover wafer W_CC may be lifted to remove the polymer residue accumulated in the pocket portion of an edge ring 412 in a cleaning process. Not only the pocket portion of the edge ring 412 but also a wafer support plate 312 may be directly exposed to plasma generated in the cleaning process, which causes to shorten the lifespan of the wafer support plate 312 which is an expensive component. Alternatively, when plasma is generated using low RF power to protect the wafer support plate 312, a process time of the cleaning process may be prolonged, thereby reducing the overall efficiency of the semiconductor manufacturing device.

In contrast, as described in FIGS. 2A, 2B, 3A and 3B, the semiconductor manufacturing devices 20a and 20b according to an example embodiment may each use a cover wafer W_C having a diameter smaller than a diameter of the mass production wafer W_M during the cleaning process. Accordingly, the wafer support plate 312 may not be exposed and only the pocket portion (for example, the second upper surface 412U2 of the edge ring 412) may be exposed to plasma generated during the cleaning process. Accordingly, the semiconductor manufacturing device 20a and 20b according to an example embodiment may efficiently perform the cleaning process.

FIG. 5 is a diagram illustrating a teaching apparatus according to an example embodiment. For brevity, only a portion of the semiconductor manufacturing device described in FIG. 2A is illustrated in FIG. 5.

Referring to FIG. 5, a teaching apparatus 30 may include a semiconductor manufacturing device 20a and a second robot 500. The teaching apparatus 30 and the semiconductor manufacturing device 20a may be interchangeably referred to as a semiconductor manufacturing apparatus. The semiconductor manufacturing device 20a may correspond to the semiconductor manufacturing devices 20a and 20b illustrated in FIGS. 2A to 3B. The second robot 500 may correspond to the second robot 5 illustrated in FIG. 1.

The second robot 500 may seat a cover wafer W_C on a wafer support plate 312 during a cleaning process. A diameter of the cover wafer W_C may be the same as or similar to a diameter of the wafer support plate 312. In an embodiment, the diameter of the cover wafer W_C may be greater than the diameter of the wafer support plate 312 by a predetermined amount. For example, the diameter of the cover wafer W_C may be greater than the diameter of the wafer support plate 312 by 0.2 mm. The predetermined amount may vary according to a size of the pocket region (i.e., the second upper surface 412US) of the edge ring 412. The second robot 500 may perform a cover wafer-ESC alignment operation to align the center of the cover wafer W_C with the center of the wafer support plate 312. Accordingly, a pocket portion of an edge ring 412 may be exposed to the outside.

The second robot 500 may seat the mass production wafer W_M (see FIG. 3A) on the wafer support plate 312 during a mass production process. A diameter of the mass production wafer W_M may be larger than the diameter of the wafer support plate 312. The second robot 500 may perform a mass production wafer-ESC alignment operation to vary a target position on the wafer support plate 312 on which the mass production wafer W_M is to be seated, by reflecting a minute change in a position of each component of the semiconductor manufacturing device. For example, a robot moving value for the second robot 500 may be continuously corrected during the mass production wafer-ESC alignment operation to accommodate the change in the position of each component.

For example, the second robot 500 may include a driver 510, a driving shaft 520, an arm 530, a hand 540, a control circuit 600, a memory 700, and a detection sensor 800.

The arm 530 may have, for example, a multi-stage shape. The arm 530 may be connected to the driving shaft 520 to enable vertical movement. The arm 530 may rotate around the driving shaft 520 due to the rotation of the driver 510 connected to the driving shaft 520.

The hand 540 may be connected to an end portion of the arm 530. The hand 540 may load the cover wafer W_C onto the wafer support plate 312 during the cleaning process. The hand 540 may load the mass production wafer W_M onto the wafer support plate 312 during the mass production process. The hand 540 may correspond to the gripper 2G of FIG. 1. The hand 540 may be adjustable to accommodate the cover wafer W_C and the mass production wafer W_M which have different diameters.

The control circuit 600 may control the operation of the second robot 500.

In an example embodiment, the control circuit 600 may control the second robot 500 to perform a cover wafer-ESC alignment operation during the cleaning process. The control circuit 600 may control the second robot 500 to perform the cover wafer-ESC alignment operation based on a first robot moving value stored in the memory 700. The first robot moving value is a fixed value for aligning the center of the cover wafer W_C with the center of the wafer support plate 312, and may be consistently applied over all cleaning process cycles. In an embodiment, the first robot moving value may be applied repeatedly over all cleaning process cycles without adjustment. In an embodiment, the first robot moving value may include position information of the center of the wafer support plate 312.

In an example embodiment, the control circuit 600 may control the second robot 500 to perform a mass production wafer-ESC alignment operation during the mass production process. The control circuit 600 may receive a second robot moving value from a previous mass production process, stored in the memory 700. Also, the control circuit 600 may receive at least one measured value from the detection sensor 800. The control circuit 600 may generate a teaching value for the second robot 500 based on the measured value received from the detection sensor 800, and may correct the second robot moving value from the previous mass production process based on the teaching value. Then, the control circuit 600 may control the second robot 500 to perform the mass production wafer-ESC alignment operation based on the corrected second robot moving value. For example, the control circuit 600 may control the second robot 500 to place the mass production wafer W_M on the wafer support plate 312 based on the corrected second robot moving value.

The memory 700 may store the robot moving value for the alignment operation between the wafer and the wafer support plate 312. For example, the control circuit 600 may store the corrected second robot moving value in the memory 700.

For example, the memory 700 may store the first robot moving value to be used in the cleaning process. The first robot moving value may be a fixed value, consistently applied in all cleaning processes.

For example, the memory 700 may store the second robot moving value used in the previous mass production process. The second robot moving value is corrected for each mass production process, allowing the second robot moving value to be a continuously variable value. For example, the memory 700 may update the stored second robot moving value based on the corrected second robot moving value for each mass production process

The detection sensor 800 may perform a sensing operation on the inside of the process chamber and generate at least one measured value. For example, the positions of components constituting the inside of the process chamber may slightly change during a process of preparing each mass production process. The detection sensor 800 may detect the slight positional changes and generate corresponding measured values. For example, when the position of an arm 530 and/or hand 540 slightly shifts through repetitive operation, the detection sensor 800 can detect the positional variation and generate corresponding measurement values. For example, the detection sensor 800 may detect a minute displacement of the Z-axis height of the wafer support plate 312 or stage caused by thermal expansion or vacuum pressure variation inside the process chamber. As illustrated in FIG. 5 as an example, the detection sensor 800 may be disposed at an upper end of the hand 540. However, this is merely exemplary, and the detection sensor 800 may be installed either inside or outside the process chamber. The detection sensor 800 may measure defects, particles, linewidth, or the like, and generate corresponding measured values.

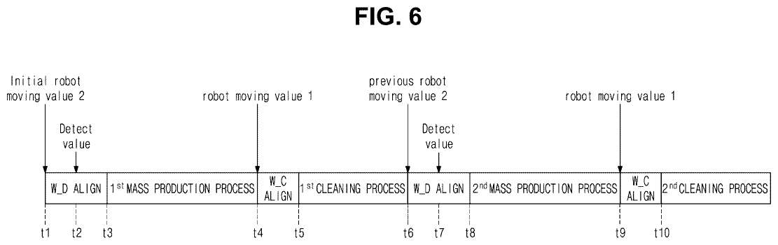

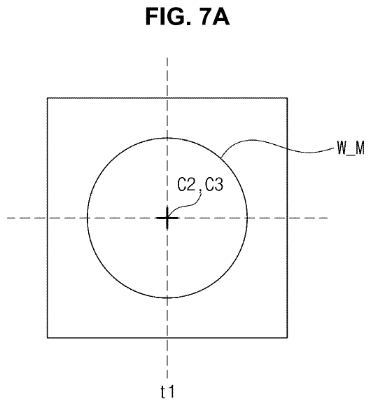

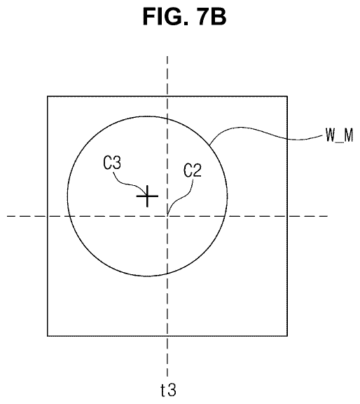

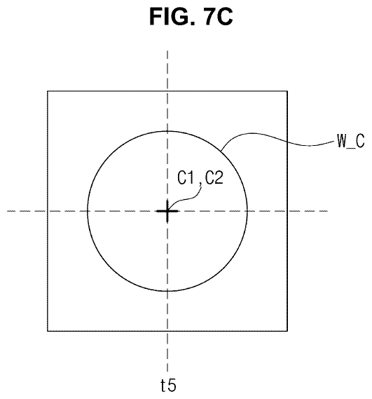

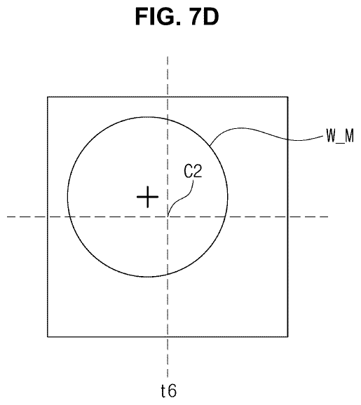

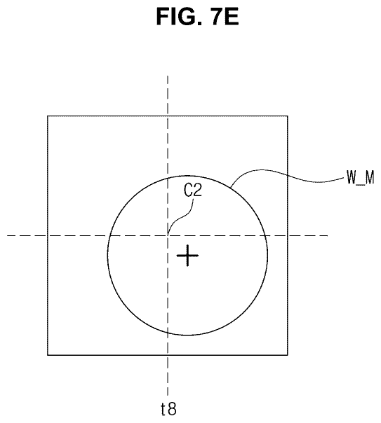

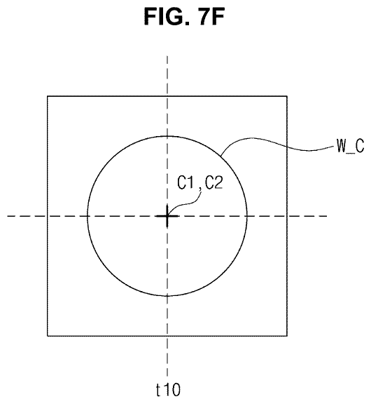

FIG. 6 is a timing diagram illustrating an example of a semiconductor manufacturing process in which a mass production process and a cleaning process are repeatedly performed. FIGS. 7A to 7F are diagrams illustrating an example of an alignment operation in a mass production process and a cleaning process according to an example embodiment.

Referring to FIG. 6, the mass production process may refer to various processes such as lithography, etching including plasma etching, ion implantation, or thin film deposition. A cleaning process using plasma may be performed between mass production processes.

Referring to FIG. 6, FIG. 7A, and FIG. 7B, a mass production wafer-ESC alignment operation may be performed between a first time point t1 and a third time point t3.

For example, at the first time point t1, the control circuit 600 may receive a second robot moving value in an initial state from the memory 700. For example, the second robot moving value in the initial state may be used to align the center C3 of the mass production wafer W_M with the center C2 of the wafer support plate 312. The control circuit 600 may control the second robot 500 to align the center C3 of the mass production wafer W_M with the center C2 of the wafer support plate 312.

At the second time point t2, the control circuit 600 may receive at least one measured value from the detection sensor 800 and generate a teaching value based on the at least one measured value. The control circuit 600 may correct the second robot moving value in the initial state based on the teaching value. The control circuit 600 may control the second robot 500 to change a position of the mass production wafer W_M based on the corrected second robot moving value. That is, the position of the production wafer W_M may be controlled to slightly vary as the positions of components constituting the process chamber are minutely changed during each mass production process. In other words, the position of the production wafer W_M may slightly vary for each mass production process according to the measured value. Accordingly, at the third time point t3, the center C3 of the mass production wafer W_M and the center C2 of the wafer support plate 312 may not be aligned with each other. The control circuit 600 may update the second robot moving value stored in the memory 700 based on the corrected second robot moving value. For example, the control circuit 600 may store the corrected second robot moving value as a new second robot moving value for the next mass production process.

Then, the first mass production process may be performed between the third time point t3 and a fourth time point t4.

Referring to FIG. 6 and FIG. 7C, a cover wafer-ESC alignment operation may be performed between the fourth time point t4 and a fifth time point t5.

For example, at the fourth time point t4, the control circuit 600 may enter a first cleaning process mode and receive the first robot moving value from the memory 700. The control circuit 600 may control the second robot 500 to align the center C1 of the cover wafer W_C with the center C2 of the wafer support plate 312, based on the first robot moving value. Accordingly, at the fifth time point t5, the center C1 of the cover wafer W_C and the center C2 of the wafer support plate 312 may be aligned with each other.

Then, the first cleaning process may be performed to clean the pocket region of the edge ring which is exposed by the cover wafer W_C. In the first mass production process performed between the third time point t3 and the fourth time point t4, contaminants such as polymers may be accumulated in the pocket portion of the edge ring 412 which is under the mass production wafer W_M. Such contaminants may be removed in the first cleaning process which is performed between the fifth time point t5 and the sixth time point t6.

Referring to FIG. 6, FIG. 7D, and FIG. 7E, a mass production wafer-ESC alignment operation may be performed between the sixth time point t6 to an eighth time point t8.

For example, at the sixth time point t6, the control circuit 600 may receive a second robot moving value in a previous state from the memory 700. For example, the second robot moving value in the previous state may correspond to the second robot moving value at the third time point t3. Accordingly, the control circuit 600 may adjust the center C3 of the mass production wafer W_M, as illustrated in FIG. 7D.

At the seventh time point t7, the control circuit 600 may receive at least one measured value from the detection sensor 800 and generate a teaching value based on the at least one measured value. The control circuit 600 may correct the second robot moving value in the previous state based on the teaching value. The control circuit 600 may control the second robot 500 to change a position of the mass production wafer W_M based on the corrected second robot moving value. Accordingly, at the eighth time point t8, the center C3 of the mass production wafer W_M may be changed.

Then, the second mass production process may be performed between the eighth time point t8 and a nineth time point t9. In an embodiment, the second mass production process may be same process as the first mass production process. For example, the first and second mass production processes may be the same process performed in the same semiconductor manufacturing device. In other words, the same mass production process may be repeatedly performed in the same semiconductor manufacturing device. The present disclosure is not limited thereto. In an embodiment, the first mass production process and the second mass production process that are different from each other may be performed in the same semiconductor manufacturing device.

Then, the cover wafer-ESC alignment operation may be performed between the ninth time point t9 and a tenth time point t10.

For example, at the ninth time point t9, the control circuit 600 may enter a second cleaning process mode and receive a first robot moving value from the memory 700. The control circuit 600 may control the second robot 500 to align the center C1 of the cover wafer W_C with the center C2 of the wafer support plate 312, based on the first robot moving value. Accordingly, at the tenth time point t10, the center C1 of the cover wafer W_C and the center C2 of the wafer support plate 312 may be aligned with each other. Then, the second cleaning process may be performed to clean the pocket region of the edge ring which is exposed by the cover wafer W_C. In the second mass production process, contaminants such as polymers may be accumulated in the pocket portion of the edge ring which is under the mass production wafer W_M. Such contaminants may be removed in the second cleaning process. For example, the first and second cleaning processes may be the same process performed in the same semiconductor manufacturing device. In other words, the same cleaning process may be repeatedly performed in the same semiconductor manufacturing device. The present disclosure is not limited thereto. In an embodiment, the first cleaning process and the second cleaning process that are different from each other may be performed in the same semiconductor manufacturing device.

As described above, the cover wafer-ESC alignment operation in the cleaning process and the mass production wafer-ESC alignment operation in the mass production process according to example embodiments may be performed independently of each other. The cover wafer-ESC alignment operation in the cleaning process may be performed based on the first robot moving value having a fixed value to align the center of the cover wafer with the center of the wafer support plate. Accordingly, the wafer support plate may not be exposed and only the pocket portion of the edge ring may be exposed to plasma, during the cleaning process. As a result, the cleaning process according to example embodiments may be efficiently performed.

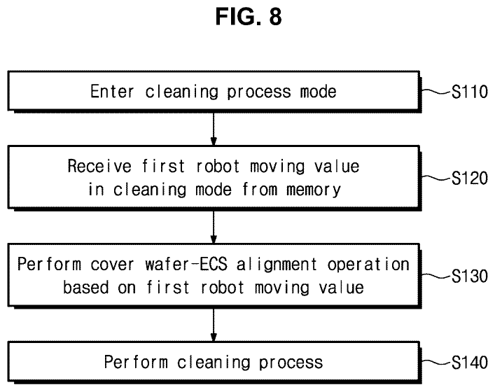

FIG. 8 is a flowchart illustrating a cover wafer-ESC alignment operation according to an example embodiment.

In operation S110, entering a cleaning mode may be performed.

In operation S120, the control circuit 600 (see FIG. 5) may receive a first robot moving value from the memory 700 (see FIG. 5). The first robot moving value may be a fixed value.

In operation S130, the control circuit 600 may control the second robot 500 (see FIG. 5) to align the center of the cover wafer with the center of the wafer support plate based on the first robot moving value. Accordingly, the center of the cover wafer and the center of the wafer support plate may be aligned with each other. A diameter of the cover wafer and a diameter of an upper surface of the wafer support plate are the same or similar, so that the pocket portion of the edge ring may be exposed to the outside.

In operation S140, the cleaning operation may be performed. The pocket portion of the edge ring is exposed to the outside, so that contaminants accumulated in the pocket portion of the edge ring may also be effectively removed by plasma.

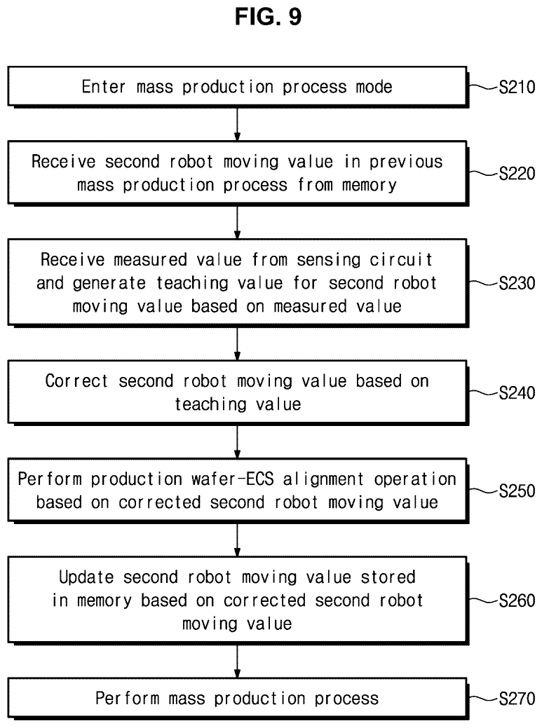

FIG. 9 is a flowchart illustrating a mass production wafer-ESC alignment operation according to an example embodiment.

In operation S210, entering a mass production mode may be performed.

In operation S220, the control circuit 600 (see FIG. 5) may receive a second robot moving value in a previous state from the memory 700 (see FIG. 5).

In operation S230, the control circuit 600 may receive at least one measured value from the detection sensor 800 (see FIG. 5) and generate a teaching value based on the at least one measured value.

In operation S240, the control circuit 600 may correct the second robot moving value in the previous state based on the teaching value.

In operation S250, the control circuit 600 may control the second robot 500 to change a position of a mass production wafer based on the corrected second robot moving value. Accordingly, the position of the mass production wafer may slightly change for each mass production process.

In operation S260, the control circuit 600 may update the second robot moving value stored in the memory 700 based on the corrected second robot moving value.

In operation S270, a mass production operation may be performed.

As described above, the mass production wafer-ESC alignment operation in the mass production process according to example embodiments may be performed independently of the cover wafer-ESC alignment operation in the cleaning process.

As set forth above, according to example embodiments, a semiconductor manufacturing device may efficiently perform a cleaning process.

While example embodiments have been shown and described above, it will be apparent to those skilled in the art that modifications and variations could be made without departing from the scope of the present inventive concept as defined by the appended claims.

What is claimed is:

1. A semiconductor manufacturing apparatus comprising:
a process chamber;
a wafer support plate disposed inside the process chamber;
an edge ring disposed inside the process chamber and surrounding the wafer support plate; and
a robot including a control circuit and a gripper,
wherein the control circuit is configured to:
control the gripper to load a dummy wafer having a first diameter on the wafer support plate during a cleaning process and load a wafer having a second diameter, greater than the first diameter, on the wafer support plate during a mass production process, the gripper being adjustable to accommodate the dummy wafer having the first diameter and the wafer having the second diameter, and
control the robot to place a center of the dummy wafer at a center of the wafer support plate during the cleaning process.

2. The apparatus of claim 1, wherein:
the robot further comprises a memory configured to store a first robot moving value for controlling the robot for the cleaning process; and
the control circuit is configured further to control the robot to place the center of the dummy wafer at the center of the wafer support plate using the first robot moving value.

3. The apparatus of claim 2,
wherein the memory is configured further to store a second robot moving value for controlling the robot for the mass production process.

4. The apparatus of claim 3, wherein:
the robot is disposed in the process chamber and further comprises a detection sensor configured to output at least one measurement value for the process chamber; and
the control circuit is configured further to correct the second robot moving value based on the at least one measurement value to generate a corrected second robot moving value.

5. The apparatus of claim 4,
wherein the control circuit is configured further to:
control the gripper to load the wafer having the second diameter for the mass production process, and
control the robot to adjust a position of the wafer based on the corrected second robot moving value.

6. The apparatus of claim 5, wherein:
the control circuit is configured further to:
update the second robot moving value stored in the memory with the corrected second robot moving value.

7. The apparatus of claim 5,
wherein the center of the wafer is not aligned with the center of the wafer support plate.

8. The apparatus of claim 1, wherein:
the edge ring is disposed to surround a side surface of the wafer support plate; and
a diameter of an upper surface of the wafer support plate is the same as the first diameter.

9. The apparatus of claim 1, wherein:
the edge ring comprises:
a first upper surface positioned at a first level higher than an upper surface of the wafer support plate;
a second upper surface positioned at a second level lower than the first level, the second upper surface closer to the upper surface of the wafer support plate than the first upper surface; and
a side surface connecting the first upper surface and the second upper surface with each other; and
the second upper surface is exposed to plasma generated during the cleaning process.

10. The apparatus of claim 9,
wherein the second upper surface is covered by the wafer during the mass production process.

11. A method of operating a semiconductor processing apparatus comprising:
performing a first mass production process on a first wafer placed on a wafer support plate which is surround by an edge ring with an upper surface including a first upper surface higher than an upper surface of the wafer support plate, a second upper surface lower than the first upper surface, and a side surface connecting the first upper surface to the second upper surface, wherein the first wafer covers the second upper surface and exposes the first upper surface and the side surface;
receiving a first robot moving value for a first cleaning process from a memory after the performing of the first mass production process;
performing a first alignment operation based on the first robot moving value to align a center of a dummy wafer with a center of the wafer support plate, wherein the dummy wafer exposes the first upper surface, the second upper surface, and the side surface; and
performing the first cleaning process on the upper surface of the edge ring after the performing of the first alignment operation.

12. The method of claim 11, further comprising:
performing, after the performing of the first cleaning process, a second mass production process on a second wafer placed on the wafer support plate;
receiving the first robot moving value from the memory for a second cleaning process after the performing of the second mass production process;
performing a second alignment operation based on the first robot moving value to align the center of the dummy wafer with the center of the wafer support plate; and
performing the second cleaning process on the upper surface of the edge ring which is contaminated during the second mass production process after the performing of the second alignment operation.

13. The method of claim 12, further comprising:
performing an alignment process of the second wafer between the first cleaning process and the second mass production process,
wherein the performing of the alignment process of the second wafer includes:
receiving a second robot moving value for the second mass production process from the memory, wherein the second robot moving value is stored in the memory during an alignment process of the first wafer performed prior to the first mass production process;
receiving at least one measurement value for a process chamber from a detection sensor;
generating a teaching value for the second robot moving value based on the at least one measurement value;
correcting the second robot moving value based on the teaching value to generate a corrected second robot moving value; and
performing a wafer alignment operation based on the corrected second robot moving value to vary a position at which the second wafer is seated on the wafer support plate, and
wherein the performing of the second mass production process is performed after the performing of the alignment process of the second wafer.

14. The method of claim 13,
wherein the performing of the alignment process of the second wafer further includes:
updating the second robot moving value, stored in the memory, in the first mass production process based on the corrected second robot moving value.

15. The method of claim 13,
wherein the center of each of the first wafer and the second wafer is not aligned with the center of the wafer support plate.

16. The method of claim 11,
wherein the first robot moving value is the same value over the first cleaning process and the second cleaning process.

17. A plasma processing apparatus comprising:
a plasma process chamber;
a wafer support plate disposed inside the plasma process chamber and configured to support one of a dummy wafer and a wafer;
an edge ring disposed inside the plasma process chamber and surrounding the wafer support plate; and
a robot including a control circuit and a gripper,
wherein the control circuit is configured to:
control the gripper to load the dummy wafer having a first diameter on the wafer support plate during a cleaning process and load the wafer having a second diameter, greater than the first diameter, on the wafer support plate during a mass production process, the gripper being adjustable to accommodate the dummy wafer having the first diameter and the wafer having the second diameter, and
control the robot to place a center of the dummy wafer at a center of the wafer support plate during the cleaning process.

18. The apparatus of claim 17, wherein:
the edge ring comprises:
a first upper surface positioned at a first level higher than an upper surface of the wafer support plate;
a second upper surface positioned at a second level lower than the first level, the second upper surface closer to the upper surface of the wafer support plate than the first upper surface; and
a side surface connecting the first upper surface and the second upper surface with each other; and
the second upper surface is exposed to plasma generated during the cleaning process.

19. The apparatus of claim 18,
wherein the second upper surface is covered by the wafer during the mass production process.

20. The apparatus of claim 17, wherein:
the edge ring is disposed to surround a side surface of the wafer support plate; and
a diameter of an upper surface of the wafer support plate is the same as a diameter of the dummy wafer.
